(19) United States
(12) Patent Application Publication
(10) Pub. No.: US 2025/0116708 A1
(43) Pub. Date: Apr. 10, 2025

(54) BATTERY CONTROL PARAMETER ESTIMATION SYSTEM AND BATTERY CONTROL PARAMETER ESTIMATION METHOD

(71) Applicant: Richtek Technology Corporation, Hsinchu (TW)

(72) Inventors: Chieh-En CHEN, Hsinchu (TW); Chung-Jen CHOU, Hsinchu (TW)

(21) Appl. No.: 18/909,910

(22) Filed: Oct. 8, 2024

Related U.S. Application Data
(60) Provisional application No. 63/589,310, filed on Oct. 10, 2023.

(30) Foreign Application Priority Data
Oct. 4, 2024 (TW) 113137976

(51) Int. Cl. G01R 31/367; G01R 31/374; G01R 31/388; H01M 10/44; H01M 10/48

(52) U.S. Cl. CPC G01R 31/367; G01R 31/374; G01R 31/388; H01M 10/443; H01M 10/486

(57) ABSTRACT

A battery control parameter estimation system includes sensing, storage, and estimation circuits. The estimation circuit determines an operation model based on an estimated control parameter signal and a battery property signal or an internal reference information. The operation model defines a control parameter, a status parameter, and a relationship therebetween, and performs an estimation operation to generate an estimation result. The estimation operation includes: dividing a limited range into multiple sections to generate multiple control parameter values; sequentially inputting the control parameter values into the operation model to obtain multiple status parameter values; checking whether a determination object satisfy a determination condition; if satisfied, determining the estimation result and ending the estimation operation; if not, taking two control parameter values corresponding to two status parameter values before and after a first crossing of a target value to define a next limited range and performing a next estimation operation.

### CROSS REFERENCE

The present invention claims priority to U.S. 63/589,310 filed on Oct. 10, 2023 and claims priority to TW 113137976 filed on Oct. 4, 2024.

### BACKGROUND OF THE INVENTION

### Field of Invention

The present invention relates to a battery control parameter estimation system; particularly, it relates to such a battery control parameter estimation system that efficiently finds the estimated result of the control parameter in a nonlinear operational model, thereby saving the system's computation time and energy consumption. The present invention also relates to a battery control parameter estimation method.

### Description of Related Art

During battery operation, changes in factors such as the battery's state of charge (SOC), material composition, battery aging, operation methods, and battery temperature lead to variations in the battery's electrical characteristics. Existing battery estimation techniques primarily update the battery's current operational model or its calculation parameters based on sensor results of the battery's related characteristics, electrical characteristic tables, and operation records. These techniques estimate the subsequent battery status based on these operation conditions. However, when certain parameters exhibit nonlinear changes or when different calculation parameters are combined, the relationships between these parameters may also result in nonlinear changes in the operation model, leading to a nonlinear operation model (i.e., nonlinear relationships between control parameters and status parameters). Furthermore, since many battery characteristic parameters are inherently nonlinear and interact with each other, the operational model for battery characteristics becomes complex. This complexity makes it difficult to calculate the control parameters using simple computations. If iterative calculations are used to solve the problem, the computation load becomes large, resulting in extended computation time and excessive energy consumption.

In this situation, using the bisection method to estimate battery control parameters may lead to erroneous results (e.g., when there is more than one solution). On the other hand, the exhaustive search method incurs a heavy computational load, consuming substantial computational resources and electrical energy.

In view of the above, to overcome the drawbacks in the prior art, the present invention proposes a battery control parameter estimation system and a battery control parameter estimation method, which can quickly find the solution to control parameters in a nonlinear operational model, thereby saving system computation time and energy consumption.

### SUMMARY OF THE INVENTION

From one perspective, the present invention provides a battery control parameter estimation system, comprising: a sensing circuit, configured to sense at least one battery property to generate at least one battery property signal; a storage circuit, configured to store at least one internal reference information; and an estimation circuit, configured to: determine an operation model based on an estimated control parameter signal and the at least one battery property signal or the at least one internal reference information, wherein the operation model defines a control parameter and a status parameter, and defines the relationship between the control parameter and the status parameter; and perform at least one round of estimation operation to generate an estimation result; wherein the estimation operation comprises: (a) dividing a limited range of the control parameter into a plurality of sections to generate corresponding a plurality of control parameter values; (b) sequentially inputting the plural control parameter values into the operation model based on a sequential direction parameter to generate corresponding plural status parameter values; (c) after generating each status parameter value, checking whether a corresponding determination object satisfies a determination condition; (d) when the determination object satisfies the determination condition, determining the estimation result and ending the at least one round of estimation operation; and (e) when all the determination objects corresponding to the plural status parameter values do not satisfy the determination condition, taking the two control parameter values corresponding to the two status parameter values that first cross a target value of the status parameter as the limited range for the next round of the estimation operation, and performing the next round of the estimation operation; wherein the plural determination objects are the plural status parameter values or the plural sections; wherein the determination condition is a node determination condition or a section determination condition corresponding to the determination object.

From another perspective, the present invention provides a battery control parameter estimation method, comprising: sensing at least one battery property with a sensing circuit to generate at least one battery property signal; storing at least one internal reference information in a storage circuit; determining an operation model with an estimation circuit based on an estimated control parameter signal and the at least one battery property signal or the at least one internal reference information, wherein the operation model defines a control parameter and a status parameter and defines the relationship between the control parameter and the status parameter; and performing at least one round of estimation operation with the estimation circuit to generate an estimation result; wherein the estimation operation comprises: (a) dividing a limited range of the control parameter into a plurality of sections to generate a plurality of corresponding control parameter values; (b) sequentially inputting the plural control parameter values into the operation model based on a sequential direction parameter to generate corresponding plural status parameter values; (c) after generating each status parameter value, checking whether a corresponding determination object satisfies a determination condition; (d) when the determination object satisfies the determination condition, determining the estimation result and ending the at least one round of estimation operation; and (e) when all the determination objects corresponding to the plural status parameter values do not satisfy the determination condition, taking the two control parameter values corresponding to the two status parameter values that first cross a target value of the status parameter as the limited range for the next round of estimation operation, and performing the next round of estimation operation; wherein the plural determination objects are the plural status parameter values or the plural sections; wherein the determination condition is a node determination condition or a section determination condition corresponding to the determination object.

In one embodiment, the at least one internal reference information includes a battery electrical characteristic table, an operation record, a calculation parameter, and/or a time counting value.

In one embodiment, the at least one battery property includes a battery voltage, a battery current, and/or a battery temperature.

In one embodiment, the control parameter is defined based on one of the at least one battery property signal or one of the at least one internal reference information.

In one embodiment, the status parameter is defined based on one of the at least one battery property signal or one of the at least one internal reference information.

In one embodiment, the estimated control parameter signal includes an operation model selection parameter, the sequential direction parameter, a first round starting point, and a first round endpoint; wherein the operation model selection parameter is used to determine the corresponding operation model; wherein the sequential direction parameter is used to indicate a sequential direction of the control parameter; wherein the first round starting point and the first round endpoint define the limited range for the first round of estimation operation.

In one embodiment, during the same round of estimation operation, the interval length of each section in the plurality of sections is equal.

In one embodiment, the step (d) of the estimation operation includes: when a difference between one of the status parameter values of the plural status parameter values and the target value is smaller than a first predetermined difference, indicating that the node determination condition is satisfied, the estimation circuit determines the estimation result based on the corresponding control parameter value and ends the at least one round of estimation operation.

In one embodiment, the step (d) of the estimation operation includes: when one of the plural sections satisfies a piecewise linear condition, indicating that the section determination condition is satisfied, the estimation circuit performs linear interpolation based on the two control parameter values and the two status parameter values corresponding to the section, and determines the estimation result based on the control parameter value obtained from the linear interpolation, and ends the at least one round of estimation operation.

In one embodiment, the piecewise linear condition includes: a difference between the two status parameter values before and after the first crossing of the target value is smaller than a second predetermined difference, or a difference between the two control parameter values corresponding to the two status parameter values is smaller than a third predetermined difference.

In one embodiment, the control parameter is a depth of discharge (DOD), and the status parameter is a battery voltage;
wherein the operation model selection parameter indicates an estimation of the depth of discharge corresponding to when the battery voltage is equal to a discharge voltage termination threshold; wherein the sequential direction parameter indicates an increasing direction of the depth of discharge; wherein the first round starting point is a present depth of discharge; wherein the first round endpoint is an upper limit of the depth of discharge; wherein the at least one battery property signal corresponding to the operation model includes the battery voltage, a battery temperature, and a battery current; wherein the at least one internal reference information corresponding to the operation model includes the depth of discharge, an open circuit voltage (OCV) table corresponding to the depth of discharge, and a battery internal resistance table corresponding to the depth of discharge and the battery temperature.

In one embodiment, the control parameter is a charging time, and the status parameter is a battery temperature; wherein the operation model selection parameter indicates an estimation of the charging time corresponding to when the battery temperature is equal to a charging temperature termination threshold; wherein the sequential direction parameter indicates a decreasing direction of the charging time; wherein the first round starting point is an upper limit charging time point; wherein the first round endpoint is a current charging time point; wherein the at least one battery property signal corresponding to the operation model includes the battery temperature; wherein the at least one internal reference information corresponding to the operation model includes a battery temperature table corresponding to the charging time and a time counting value.

I

The present invention, compared to the prior art, has at least the following advantages:
First, the present invention avoids the issue in the bisection method where the correct solution cannot be found when multiple possible solutions exist.
Second, the present invention addresses the problem of excessive computational load and poor accuracy in the exhaustive search method.
Third, the present invention adopts a multi-stage method to narrow down the computational range and increase computational density, thereby reducing computational load while ensuring computational accuracy.
Fourth, the present invention explicitly specifies the range to be analyzed, focusing only on the critical data portions for computation, thus avoiding interference from extraneous data on the calculation results.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a module block diagram of a battery control parameter estimation system in one embodiment of the present invention.

FIG. 2 is a module block diagram of a battery control parameter estimation system in another embodiment of the present invention.

FIG. 3 is a flowchart of the operational steps of a battery control parameter estimation method in one embodiment of the present invention.

FIG. 4 is a flowchart of the estimation operation in one embodiment of the present invention.

FIGS. 5A to 5D illustrate a more specific embodiment of the battery control parameter estimation method according to the present invention.

FIGS. 5A and 5B show schematic diagrams of the related results of the weighted fuzzifier 111 and the voltage difference fuzzifier 112 in the algorithm for estimating the SOC of a battery.

FIGS. 6A and 6B illustrate another more specific embodiment of the battery control parameter estimation method according to the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

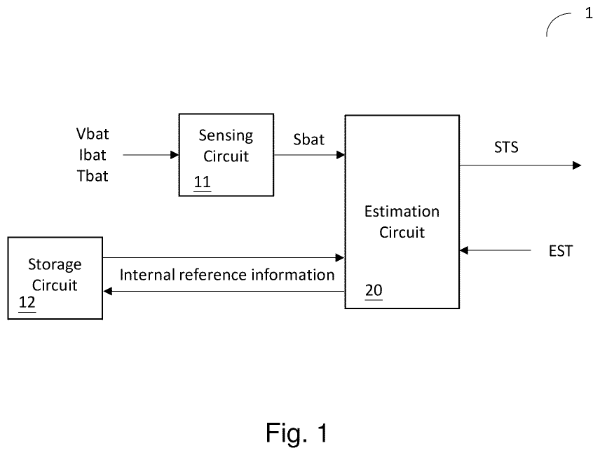

Please refer to FIG. 1, which is a module block diagram of a battery control parameter estimation system in one embodiment of the present invention. As shown in FIG. 1, the battery control parameter estimation system 1 includes a sensing circuit 11, a storage circuit 12, and an estimation circuit 20. The sensing circuit 11 is used to sense at least one battery property of the battery to generate at least one corresponding battery property signal Sbat. The battery properties may include, but are not limited to, a battery voltage Vbat, a battery current Ibat, and/or a battery temperature Tbat. The storage circuit 12 is used to store at least one internal reference information. In one embodiment, the internal reference information includes a battery electrical characteristic table, an operation record, a calculation parameter, and/or a time counting value. The estimation circuit 20 is used to determine an operation model based on the estimated control parameter signal EST and at least one battery property signal Sbat or at least one internal reference information. The operation model defines the control parameter and the status parameter and defines the relationship between the control parameter and the status parameter. The estimation circuit 20 also performs an estimation operation to generate an estimation result STS.

It should be noted that the battery electrical characteristic table may include, but is not limited to, a table comparing different battery electrical characteristics or the relationships between battery electrical characteristics and battery properties. For example, it may include an open-circuit voltage vs. depth of discharge table at different battery temperatures, a state of charge vs. open-circuit voltage table, or other tables related to battery electrical characteristics.

It should be noted that the operation record may include, but is not limited to, historical data of the battery, which can display various battery parameters over time, such as the battery voltage, battery current, and battery temperature at different time points, or other tables related to the historical record of battery parameters. These historical records can be used to calculate the required data, such as the battery current or the amount of charge at a specific time. Additionally, the operation record provides the data needed by the operation model to determine the parameters and specific conditions.

It should be noted that the calculation parameters may include, but are not limited to, various battery parameters used in the battery property signal, the battery electrical characteristic table, or the operation record, such as battery voltage, battery current, battery temperature, open-circuit voltage, depth of discharge, state of charge, and other parameters related to battery characteristics.

It should be noted that the time counting value may include, but is not limited to, the charging time counting value, discharging time counting value, the estimation operation counting value for each round of estimation operation, and the status parameter value generation counting value for each generated status parameter value, or other time counting values related to battery operations.

It should be noted that the estimation circuit 20 determines the control parameter and status parameter of the operation model based on the estimated control parameter signal EST and obtains, calculates, or derives the functional relationship between the control parameter and the status parameter based on at least one battery property signal Sbat or at least one internal reference information, to determine the operation model. The functional relationship between the control parameter and the status parameter may be a nonlinear functional relationship.

The estimation operation includes:
(a) The estimation circuit 20 divides the limited range of the control parameter of the operation model into a plurality of sections to generate a plurality of corresponding control parameter values;
(b) The estimation circuit 20 sequentially inputs the plural control parameter values into the operation model based on the sequential direction indicated by the sequential direction parameter to generate corresponding plural status parameter values;
(c) After generating each status parameter value, the estimation circuit 20 checks whether the corresponding determination object satisfies the determination condition;
(d) When the determination object satisfies the determination condition, the estimation circuit 20 determines the estimation result and ends the estimation operation; and
(e) When all the determination objects corresponding to the plural status parameter values in the current estimation operation do not satisfy the determination condition, the estimation circuit 20 takes the two control parameter values corresponding to the two status parameter values that first cross the target value of the status parameter and defines the limited range for the next round of estimation operation, and performs the next round of estimation operation; wherein the plural determination objects are the plural status parameter values or the plural sections; wherein the determination condition is a node determination condition or a section determination condition corresponding to the determination object.

In one embodiment, the control parameter is defined based on one of the at least one battery property signal or one of the at least one internal reference information. For example, the control parameter may be the depth of discharge, the time counting value, the battery voltage, the battery current, the battery temperature, the parameter recorded in the operation record, or the calculation parameter. The estimation circuit 20 may select or define the control parameter based on the estimated control parameter signal EST from the battery property signal or internal reference information.

In one embodiment, the status parameter includes one of the at least one battery property signal or one of the at least one internal reference information. For example, the status parameter may be the depth of discharge, the time counting value, the battery voltage, the battery current, the battery temperature, the parameter recorded in the operation record, or the calculation parameter. The estimation circuit 20 may select or define the status parameter based on the estimated control parameter signal EST from the battery property signal or internal reference information.

In one embodiment, the estimated control parameter signal includes an operation model selection parameter, a sequential direction parameter, a first round starting point, and a first round endpoint; wherein the operation model selection parameter is used to indicate the corresponding operation model; wherein the sequential direction parameter is used to indicate the sequential direction in which the plural control parameter values are input into the operation model; wherein the first round starting point and the first round endpoint define the limited range for the first round of the estimation operation.

The operation model selection parameter includes related data necessary for selecting or deriving the operation model so that the estimation circuit 20 can obtain or derive the operation model used in the estimation operation, which will be further illustrated with examples later.

In one embodiment, during the same round of estimation operation, the interval length of each section in the plurality of sections is equal. The predetermined section intervals may be fixed, and the interval lengths of the predetermined sections in different steps (a) of different rounds of the estimation operation may vary. In one embodiment, the interval length of the current predetermined section is greater than the interval length of the predetermined section in the next round.

In one embodiment, the step (d) of the estimation operation includes: when a difference between one of the plural status parameter values and the target value is smaller than a first predetermined difference, indicating that the node determination condition is satisfied, the estimation circuit determines the estimation result based on the control parameter value corresponding to the status parameter value and ends the at least one round of estimation operation. For example, during the process of sequentially comparing the status parameter values with the target value and generating corresponding comparison results, once the difference between the status parameter value and the target value is smaller than the first predetermined difference, the corresponding control parameter value is determined as the estimation result, and the at least one round of estimation operation is ended. The subsequent comparison steps, where the remaining status parameter values are compared with the target value and the difference is obtained, do not need to be continued, and the next round of estimation operation does not need to be performed.

In one embodiment, the step (d) of the estimation operation includes: when one of the plural sections satisfies the piecewise linear condition, indicating that the section determination condition is satisfied, the estimation circuit performs linear interpolation based on the two control parameter values and the two status parameter values corresponding to the section, and determines the estimation result based on the control parameter value obtained from the linear interpolation, and ends the at least one round of estimation operation. In one embodiment, once a section that satisfies the piecewise linear condition appears, linear interpolation is performed on the corresponding status parameter values and control parameter values of the section. The obtained control parameter value is judged to be the estimation result, and the at least one round of estimation operation is ended. The subsequent checks for whether other sections satisfy the piecewise linear condition do not need to be continued, and the next round of estimation operation does not need to be performed.

In one embodiment, the piecewise linear condition includes: the difference between the two status parameter values before and after the first crossing of the target value is smaller than a second predetermined difference, or the difference between the two control parameter values corresponding to the two status parameter values is smaller than a third predetermined difference.

It should be noted that the first predetermined difference, the second predetermined difference, and the third predetermined difference are determined according to actual needs, as long as they meet the requirements for determining the estimation result.

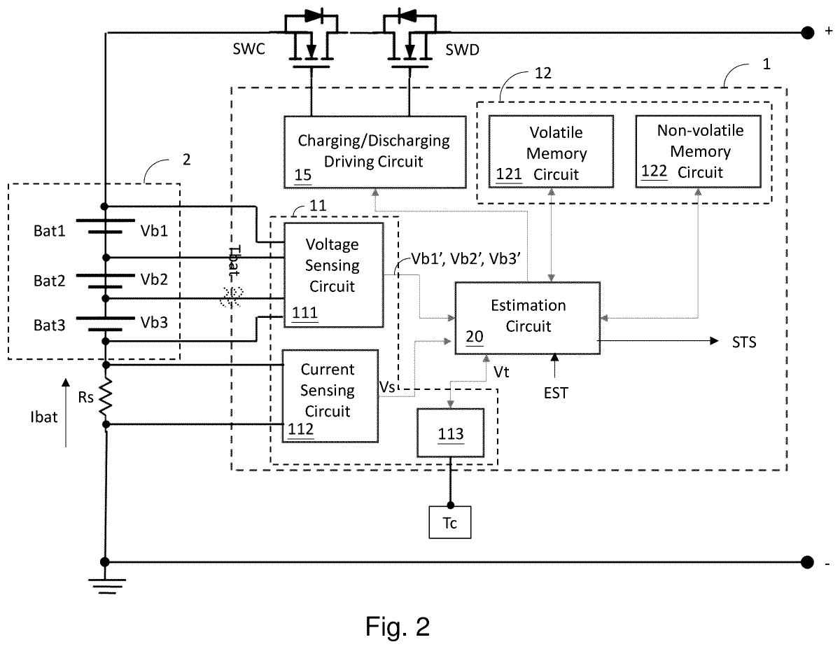

Please refer to FIG. 2, which is a module block diagram of a battery control parameter estimation system in another embodiment of the present invention. As shown in FIG. 2, the battery control parameter estimation system 1 includes a sensing circuit 11, a memory circuit 12, a charging/discharging driving circuit 15, and an estimation circuit 20. In this embodiment, the sensing circuit 11 includes, for example, a voltage sensing circuit 111, a current sensing circuit 112, and a temperature sensing circuit 113.

In this embodiment, the voltage sensing circuit 111 is coupled to a battery pack 2 and is used to sense the battery voltages Vb1, Vb2, and Vb3 of each battery (Bat1, Bat2, Bat3) connected in series in the battery pack 2, and correspondingly generate battery voltage sensing signals Vb1′, Vb2′, and Vb3′. The battery voltage sensing signals Vb1′, Vb2′, and Vb3′ can be stored in a volatile memory circuit 121 for calculation or transmission. The battery current sensing signal Vs and battery temperature sensing signal Vt, as described later, can also be stored in the volatile memory circuit 121, which will not be further elaborated. In one embodiment, the voltage sensing circuit 111 may include, but is not limited to, an analog-to-digital converter (ADC) and a multiplexer (MUX) to implement the voltage sensing function. The structure and function of the analog-to-digital converter and the multiplexer are well-known to those skilled in the art and will not be further described.

The current sensing circuit 112 is coupled to a sensing resistor Rs to sense the battery current Ibat flowing through Bat1, Bat2, and Bat3, and generate a battery current sensing signal Vs, wherein the sensing resistor Rs is connected in series with the battery pack 2. The temperature sensing circuit 113 is coupled to a thermistor Tc to sense the battery temperature Tbat and generate a battery temperature sensing signal Vt. The battery voltage sensing signals Vb1′, Vb2′, Vb3′, battery current sensing signal Vs, and battery temperature sensing signal Vt are all considered battery property signals Sbat.

It should be noted that, in this embodiment, each battery property signal Sbat corresponds to only one battery, Bat1, Bat2, or Bat3. Similarly, the internal reference information, the estimated control parameter signal EST, the sequential direction parameter, the estimation result STS, the control parameter, the control parameter value, the battery property signal, the operation model, the status parameter, and the status parameter value, among other battery-related parameters or values, also correspond to only one battery, Bat1, Bat2, or Bat3. That is, each battery, Bat1, Bat2, or Bat3, has its own corresponding battery property signals, internal reference information, estimated control parameter signal EST, estimation result STS, control parameter, control parameter value, operation model, status parameter, status parameter value, and other battery-related parameters or values, as well as its own corresponding battery properties.

In this embodiment, the memory circuit 12 includes a volatile memory circuit 121 and a non-volatile memory circuit 122. In one embodiment, the non-volatile memory circuit 122 may be used to store at least one internal reference information. The non-volatile memory circuit 122 can, for example, store the operation model, battery electrical characteristic table, operation record, calculation parameters, target values, determination conditions, first round starting point, first round endpoint, predetermined section intervals, first predetermined difference, second predetermined difference, third predetermined difference, or piecewise linear conditions, etc. In one embodiment, the volatile memory circuit 121 can be used to temporarily store battery property signals, estimation results, control parameter values, status parameter values, comparison results, time counting values such as charging time and discharging time, or differences, etc.

The charging/discharging driving circuit 15 is coupled between the estimation circuit 20 and the power switches SWC and SWD, and is used to drive and operate the power switches SWC and SWD according to the operation signals of the estimation circuit 20 to charge or discharge the battery pack 2. This is well-known to those skilled in the art and will not be further elaborated.

In one embodiment, the estimation circuit 20 determines the operation model based on the estimated control parameter signal EST and at least one battery property signal or at least one internal reference information. The operation model defines the control parameter and the status parameter and defines the relationship between the control parameter and the status parameter. The relationship between the control parameter and the status parameter may be a nonlinear functional relationship. This nonlinear functional relationship may already be stored in the memory circuit 12 and can be directly selected and obtained. If this nonlinear functional relationship needs to be calculated or converted, the estimation circuit 20 obtains the necessary information for the calculation or conversion from the battery property signal or internal reference information based on the estimated control parameter signal EST, as needed in practical applications, to determine the operation model. After determining the operation model, the estimation circuit 20 performs an estimation operation based on the sequential direction parameter and the first round starting point and endpoint in the estimated control parameter signal EST to generate the estimation result STS.

In this embodiment, as shown in FIG. 2, when the estimation circuit 20 obtains the current battery property signal, it can update the internal reference information, such as updating the parameters in the battery reference internal resistance and depth of discharge table. The estimation circuit 20 can set the operation model based on the estimated control parameter signal EST and configure the sequential direction parameter to perform the estimation operation and generate the estimation result. The estimation result can be further used to predict when the battery charge will be fully consumed, or when it is necessary to limit the load in advance (e.g., stop charging) to prevent the battery temperature Tbat from rising.

The present invention allows the determination of the corresponding control parameter value, as the estimation result, in a more efficient and energy-saving manner, based on one or more specific conditions of the status parameter. The estimation result can then be further used to predict the battery's status according to actual needs. There are many applications for converting the estimation result into the predicted battery status in practical applications, but this is not the focus of the present invention. Therefore, the following descriptions provide examples without elaborating on the various applications for predicting the battery's status.

This embodiment is intended to illustrate the application of the present invention to a rechargeable battery system. The estimation operation in this embodiment is the same as that in the embodiment shown in FIG. 1. Please refer to the description of FIG. 1 for further details.

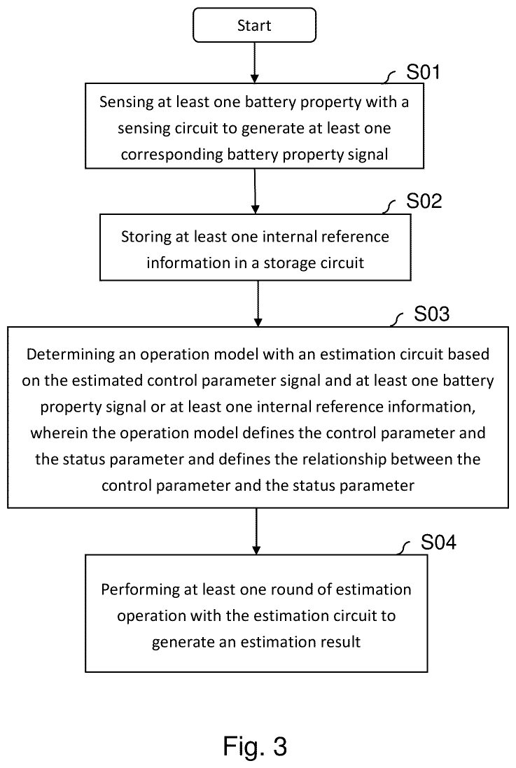

FIG. 3 is a flowchart of the operational steps of a battery control parameter estimation method in one embodiment of the present invention. As shown in FIG. 3, the battery control parameter estimation method comprises:
Step S01: sensing at least one battery property with a sensing circuit to generate at least one corresponding battery property signal;
Step S02: storing at least one internal reference information in a storage circuit;
Step S03: determining an operation model with an estimation circuit based on the estimated control parameter signal and at least one battery property signal or at least one internal reference information, wherein the operation model defines the control parameter and the status parameter and defines the relationship between the control parameter and the status parameter; and
Step SO4: performing at least one round of estimation operation with the estimation circuit to generate an estimation result.

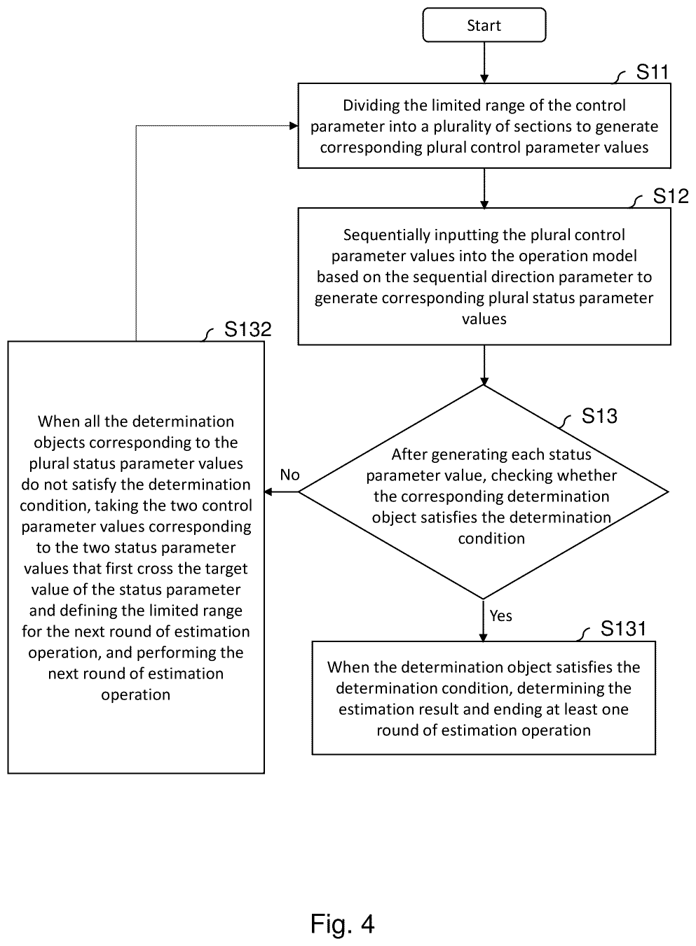

FIG. 4 is a flowchart of the estimation operation in one embodiment of the present invention. As shown in FIG. 4, the estimation operation comprises:
Step S11: dividing the limited range of the control parameter into a plurality of sections to generate corresponding plural control parameter values;
Step S12: sequentially inputting the plural control parameter values into the operation model based on the sequential direction parameter to generate corresponding plural status parameter values;
Step S13: after generating each status parameter value, checking whether the corresponding determination object satisfies the determination condition;
Step S131: when the determination object satisfies the determination condition, determining the estimation result and ending at least one round of estimation operation;
Step S132: when all the determination objects corresponding to the plural status parameter values do not satisfy the determination condition, taking the two control parameter values corresponding to the two status parameter values that first cross the target value of the status parameter and defining the limited range for the next round of estimation operation, and performing the next round of estimation operation.

In a more specific embodiment, the control parameter may be the depth of discharge (DOD), and the status parameter may be the battery voltage Vbat, based on the estimated control parameter signal EST. The operation model selection parameter of the estimated control parameter signal EST indicates, for example, the estimation of the depth of discharge corresponding to when the battery voltage Vbat equals the discharge voltage termination threshold. The first round starting point of the estimated control parameter signal EST may be the current depth of discharge. The first round endpoint may be the upper limit of the depth of discharge. The battery property signals corresponding to the operation model may include the battery voltage Vbat, battery temperature Tbat, and discharge current Ibat; the internal reference information corresponding to the operation model may include an open-circuit voltage (OCV) vs. depth of discharge characteristic table and a battery internal resistance vs. open-circuit voltage and battery temperature characteristic table. The sequential direction parameter indicates the increasing direction of the current depth of discharge toward the upper limit of the depth of discharge, i.e., the sequential direction indicates the increasing direction of the depth of discharge. The estimation circuit 20 determines the operation model based on the estimated control parameter signal EST and the corresponding battery property signal and internal reference information. Further details will be provided later.

In one embodiment, the control parameter may be the charging time, and the status parameter may be the battery temperature Tbat. The estimated control parameter signal EST indicates the estimation of the charging time corresponding to when the battery temperature Tbat equals the charging temperature termination threshold. The battery property corresponding to the operation model may include the battery temperature Tbat; the internal reference information corresponding to the operation model may include a battery temperature vs. charging time characteristic table. The first round starting point may be the upper limit charging time, and the first round endpoint may be the current charging time, with the sequential direction being the decreasing direction of the charging time. The estimation circuit 20 determines the operation model based on the estimated control parameter signal EST and the corresponding battery property signal and internal reference information. Further details will be provided later.

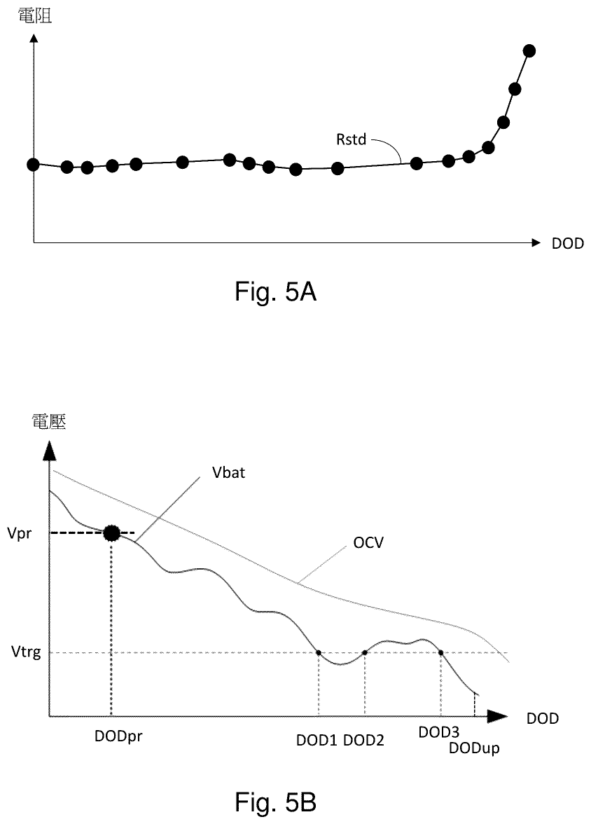

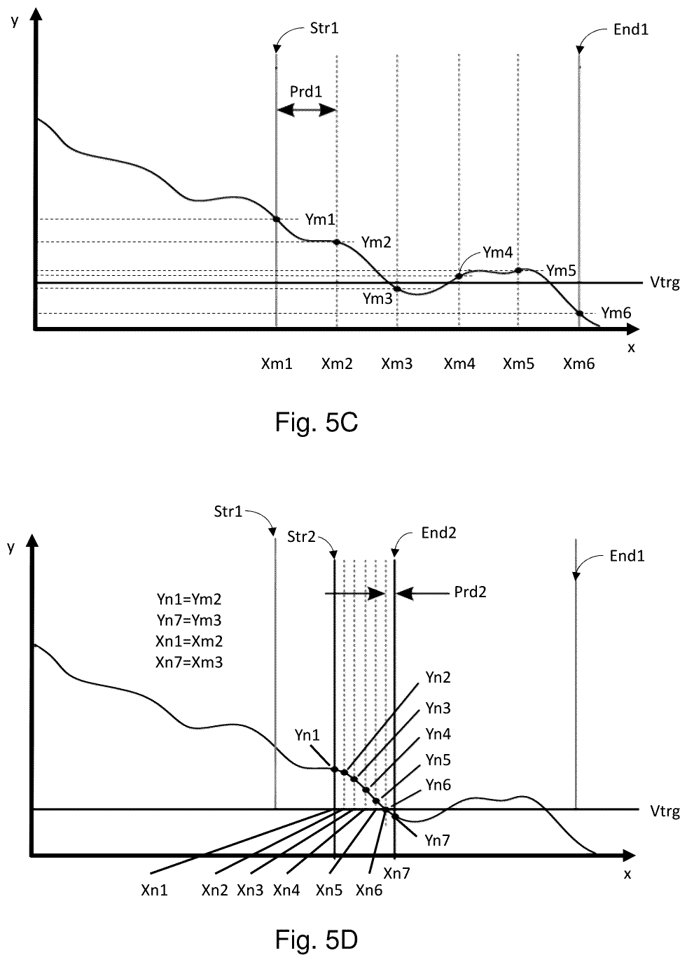

FIGS. 5A to 5D illustrate a more specific embodiment of the battery control parameter estimation method according to the present invention. This embodiment shows a method for estimating the depth of discharge when the battery voltage equals the discharge voltage termination threshold Vtrg. FIG. 5A shows a characteristic curve of the battery reference internal resistance Rstd at different depths of discharge (DOD). Observing the characteristic curve in FIG. 5A, the reference internal resistance Rstd has a nonlinear and non-monotonic relationship with the depth of discharge DOD, indicating that multiple depth of discharge DOD values may satisfy the condition of being equal to the discharge voltage termination threshold Vtrg. The battery reference internal resistance Rstd refers to the battery internal resistance under no load (open circuit) at 25° C. As shown in FIG. 5B, this operation model has three solutions for the depth of discharge DOD when the battery voltage equals the discharge voltage termination threshold Vtrg, namely DOD1, DOD2, and DOD3. Since the function corresponding to this operation model is not a one-to-one monotonic function, scanning is required to solve the problem. In this embodiment, the minimum depth of discharge DOD is set as the target for solving, aiming to find the depth of discharge DOD that first reaches the discharge voltage termination threshold Vtrg, which is the target solution DOD1, the depth of discharge closest to the current depth of discharge DODpr.

FIG. 5B shows the relationship between the depth of discharge DOD, the battery voltage Vbat, and the open-circuit voltage (OCV). As shown in FIG. 5B, in this embodiment, the higher the depth of discharge DOD, the lower the open-circuit voltage OCV. However, the relationship between the battery voltage Vbat and the open-circuit voltage OCV must also consider the effects of the battery current Ibat and battery internal resistance R.

In this embodiment, the control parameter is the depth of discharge DOD, and the status parameter is the battery voltage Vbat. The estimated control parameter signal EST indicates the estimation of the depth of discharge corresponding to when the battery voltage Vbat equals the discharge voltage termination threshold Vtrg. The battery property signals corresponding to the operation model may include the battery voltage Vbat, battery temperature Tbat, and discharge current Ibat. The internal reference information corresponding to the operation model may include an open-circuit voltage vs. depth of discharge characteristic table and a battery internal resistance vs. open-circuit voltage and battery temperature characteristic table. The sequential direction indicates the increasing direction of the depth of discharge. In this embodiment, the first round starting point is the current depth of discharge DODpr, and the first round endpoint is the upper limit of the depth of discharge DODup. Generally, the upper limit of the depth of discharge DODup is 100%. In this embodiment, the operation model describes the functional relationship between the depth of discharge DOD and the battery voltage Vbat under specific conditions. In this embodiment, the specific conditions include a specific battery temperature Tbat, a specific battery current Ibat, and a specific battery internal resistance.

FIG. 5C shows that the depth of discharge DOD is replaced by the control parameter x, and the battery voltage Vbat is replaced by the status parameter y. The sequential direction parameter indicates that the sequential direction is the increasing direction of the control parameter x, representing that in the increasing direction of the control parameter x, the first solution that meets the determination condition is found. The first round starting point is Str1, and the first round endpoint is End1. The range between Str1 and End1 is the limited range. The limited range is divided into a plurality of sections, with each section having a fixed predetermined section interval Prd1. For example, but not limited to, as shown in FIG. 5C, the range between Str1 and End1 is divided into five sections, generating six control parameter values Xm1, Xm2, Xm3, Xm4, Xm5, and Xm6 corresponding to the sequential direction. The estimation operation inputs the control parameter values Xm1, Xm2, Xm3, Xm4, Xm5, and Xm6 into the corresponding operation model in the sequential direction and generates six corresponding status parameter values Ym1, Ym2, Ym3, Ym4, Ym5, and Ym6. After generating each status parameter value Ym1, Ym2, Ym3, Ym4, Ym5, and Ym6, the status parameter value is compared with the target value, which is the discharge voltage termination threshold Vtrg, and corresponding comparison results are generated sequentially. The estimation circuit sequentially determines whether the comparison results satisfy the determination condition.

In one embodiment, the plural determination objects may be the plural status parameter values Ym1, Ym2, Ym3, Ym4, Ym5, and Ym6, and the determination condition may include, but is not limited to, a node determination condition. The node determination condition may be, for example, that the difference between one of the status parameter values Ym1, Ym2, Ym3, Ym4, Ym5, and Ym6 and the discharge voltage termination threshold Vtrg is smaller than the first predetermined difference. When the determination object (one of the status parameter values Ym1, Ym2, Ym3, Ym4, Ym5, and Ym6) satisfies the node determination condition (the difference between the status parameter value and the discharge voltage termination threshold Vtrg is smaller than the first predetermined difference), the node determination condition is satisfied. The estimation circuit 20 determines the control parameter value (one of Xm1, Xm2, Xm3, Xm4, Xm5, and Xm6) corresponding to the status parameter value that satisfies the node determination condition as the estimation result and ends the estimation operation. In other words, the control parameter values Xm1, Xm2, Xm3, Xm4, Xm5, and Xm6 are sequentially input into the operation model, corresponding to the six status parameter values Ym1, Ym2, Ym3, Ym4, Ym5, and Ym6 of the operation model. Each status parameter value is sequentially compared with the discharge voltage termination threshold Vtrg, and corresponding differences are generated. Once a difference smaller than the first predetermined difference is found, the estimation result is generated, and the subsequent control parameter values are not input into the operation model.

In another embodiment, the plural determination objects may be the plural status parameter values Ym1, Ym2, Ym3, Ym4, Ym5, and Ym6, defining plural sections. For example, status parameter values Ym1 and Ym2 define the first section, and status parameter values Ym2 and Ym3 define the second section, and so on. The determination condition may be a section determination condition. The section determination condition may include, but is not limited to, the difference between the two status parameter values before and after the first crossing of the target value being smaller than the second predetermined difference, or the difference between the two control parameter values corresponding to the two status parameter values being smaller than the third predetermined difference. When one of the plural sections satisfies the piecewise linear condition and the corresponding section determination condition, the two control parameter values, i.e., two consecutive control parameter values among Xm1, Xm2, Xm3, Xm4, Xm5, and Xm6, and the two corresponding status parameter values, i.e., two consecutive status parameter values among Ym1, Ym2, Ym3, Ym4, Ym5, and Ym6, are used for linear interpolation, and the control parameter value obtained from the linear interpolation is determined as the estimation result. Once the estimation result is generated, the subsequent control parameter values are not input into the operation model.

In this embodiment, as shown in FIG. 5C, when none of the plural status parameter values in the first round of the estimation operation satisfies the node determination condition, the estimation circuit defines the next limited range based on the two control parameter values Xm2 and Xm3 corresponding to the two consecutive status parameter values Ym2 and Ym3 that first cross the target value (i.e., the discharge voltage termination threshold Vtrg) and then performs the next round of estimation operation. The next round of estimation operation includes dividing the new limited range defined by the control parameter values Xm2 and Xm3 into plural sections, inputting them into the operation model, and sequentially checking whether the corresponding determination objects satisfy the determination condition until the determination condition is satisfied, and the estimation result is generated, as shown in FIG. 5D.

FIG. 5D shows that in the first round of estimation operation illustrated in FIG. 5C, none of the plural status parameter values Ym1, Ym2, Ym3, Ym4, Ym5, Ym6 satisfied the node determination condition. Therefore, the two consecutive status parameter values Ym2 and Ym3, which first crossed the discharge voltage termination threshold Vtrg, and their corresponding control parameter values Xm2 and Xm3, are defined as the limited range for the next round of estimation operation, i.e., the new limited range. The new starting point is Str2, and the new endpoint is End2. The range between Str2 and End2 forms the new limited range. This new limited range is divided into plural sections, each with a new fixed predetermined section interval Prd2. For example, but not limited to, as shown in FIG. 5D, the range between Str2 and End2 is divided into six sections, generating seven control parameter values Xn1, Xn2, Xn3, Xn4, Xn5, Xn6, and Xn7 marked sequentially according to the direction parameter. The estimation operation inputs control parameter values Xn1, Xn2, Xn3, Xn4, Xn5, Xn6, and Xn7 into the operation model in sequence, generating seven corresponding status parameter values Yn1, Yn2, Yn3, Yn4, Yn5, Yn6, and Yn7 as the new determination objects. The plural status parameter values Yn1, Yn2, Yn3, Yn4, Yn5, Yn6, and Yn7 are then compared with the target value, i.e., the discharge voltage termination threshold Vtrg, generating new plural comparison results, which are sequentially checked to determine whether the node determination condition is satisfied.

The node determination condition may include, but is not limited to, the difference between one of the status parameter values Yn1, Yn2, Yn3, Yn4, Yn5, Yn6, and Yn7 and the discharge voltage termination threshold Vtrg being smaller than the first predetermined difference. If the determination object (one of the status parameter values Yn1, Yn2, Yn3, Yn4, Yn5, Yn6) satisfies the node determination condition (i.e., the difference between the status parameter value and the discharge voltage termination threshold Vtrg is smaller than the first predetermined difference), the node determination condition is satisfied. The estimation circuit 20 then determines the control parameter value corresponding to the status parameter value that satisfies the node determination condition (one of Xn1, Xn2, Xn3, Xn4, Xn5, Xn6) as the estimation result, ending the estimation operation. In other words, after sequentially inputting the control parameter values Xn1, Xn2, Xn3, Xn4, Xn5, Xn6, and Xn7 into the operation model and generating the corresponding status parameter values Yn1, Yn2, Yn3, Yn4, Yn5, Yn6, and Yn7 of the operation model, the status parameter values are compared sequentially with the discharge voltage termination threshold Vtrg. The corresponding differences are checked sequentially, and once the difference is smaller than the first predetermined difference, the estimation result is generated, and further input of control parameter values Xn1, Xn2, Xn3, Xn4, Xn5, Xn6, and Xn7 into the operation model is stopped.

For example, in this embodiment, when the difference between status parameter value Yn6 and the discharge voltage termination threshold Vtrg is smaller than the first predetermined difference, the node determination condition is satisfied, and the estimation result is generated, determining that the depth of discharge corresponding to the battery voltage Vbat equal to the discharge voltage termination threshold Vtrg is the control parameter value Xn6. The further input of control parameter value Xn7 into the operation model is stopped, and status parameter value Yn7 is not generated. Furthermore, as shown in FIG. 5D, since status parameter value Yn1 equals status parameter value Ym2, status parameter value Yn7 equals status parameter value Ym3, control parameter value Xn1 equals control parameter value Xm2, and control parameter value Xn7 equals control parameter value Xm3, the corresponding control and status parameter values from the first round can be directly used in the second round of estimation, reducing the time required to calculate the differences between status parameter values Yn1 and Yn7.

For clarity, in this embodiment, the control parameter is a single variable, namely, the depth of discharge DOD, while other parameters, such as the discharge current Ibat, battery internal resistance R, and battery temperature Tbat, are fixed conditions. However, the present invention is not limited to this. According to the invention, the control parameter can include multiple variables. For instance, in addition to the depth of discharge DOD, the control parameter can also include discharge current Ibat, battery internal resistance R, and battery temperature Tbat. The current battery status, which serves as the starting point for the first round of the estimation operation, can correspond to the current depth of discharge DODpr, current discharge current, current battery internal resistance, and current battery temperature. The status parameter remains the battery voltage Vpr, and the target value is still set as the discharge voltage termination threshold Vtrg. In other words, the present invention can be extended to applications involving the solving of multiple control parameters. Furthermore, the functional relationship between the battery voltage Vbat and the depth of discharge DOD, discharge current Ibat, battery internal resistance R, and battery temperature Tbat, i.e., the operation model, is: battery voltage Vbat=function f(DOD, Ibat, R, Tbat). Therefore, by incorporating the relationship between the open-circuit voltage OCV, battery current Ibat, and battery internal resistance R, for example, the relationship can be expressed as: Vbat=OCV(DOD)+Ibat*R(DOD, Tbat).

Further explaining, estimating the depth of discharge DOD corresponding to when the battery voltage Vbat equals the discharge voltage termination threshold Vtrg can be seen as solving the function f(DOD, Ibat, R, Tbat)=Vtrg. The subsequent steps, which include checking whether the corresponding determination object satisfies the determination condition, determining the estimation result when the determination object satisfies the determination condition, and ending at least one round of estimation operation, or when none of the determination objects corresponding to the plural status parameter values satisfy the determination condition, defining the next round's limited range based on the two status parameter values that first crossed the target value, and performing the next round of estimation operation, are similar to the embodiment illustrated in FIGS. 5A to 5D, except for adding more control variables. These additional steps are not described further here.

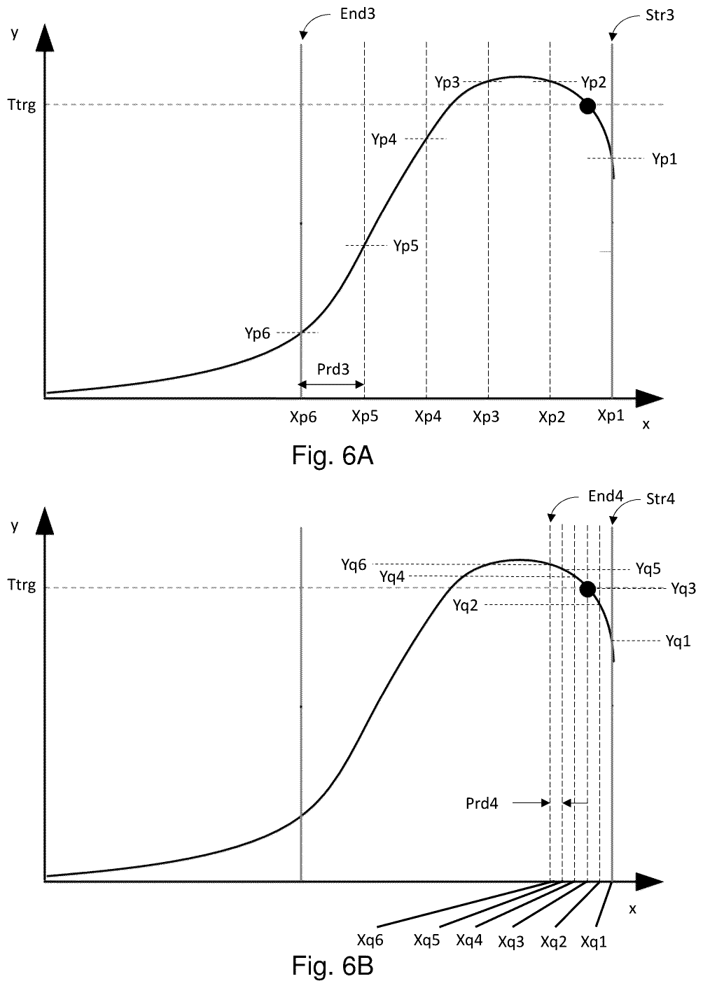

FIGS. 6A and 6B illustrate another more specific embodiment of the battery control parameter estimation method according to the present invention. This embodiment shows the estimation of the charging time Time_chg corresponding to when the battery temperature Tbat equals the charging temperature termination threshold Ttrg, starting at room temperature (25° C.).

FIGS. 6A and 6B show the relationship between the charging time Time_chg and the battery temperature Tbat. As shown in FIGS. 6A and 6B, the battery status corresponds to the control parameter (x-axis) being the charging time Time_chg, while the status parameter (y-axis) is the battery temperature Tbat. The target value is set as the charging temperature termination threshold Ttrg. In this embodiment, the functional relationship between the battery temperature Tbat and the charging time Time_chg, i.e., the operation model, is: battery temperature Tbat=function f(Time_chg).

To solve for the battery temperature Tbat=function f(Time_chg), the relationship between various parameters and internal tables can be roughly expressed as: Ichg1=Ichg_cc, Ichg2=(Vchg−OCV(SOC))/Res(Tbat, SOC), SOC=(SOC*Cap+Ichg*Time_chg)/Cap, Tbat delta=(Ichg\hat{ }2*Res(Tbat, SOC)) *Qres. Here, Ichg_cc is the current value during constant current charging, Ichg2 is the current during constant voltage charging, and Ichg is the actual charging current, which is the smaller of Ichg1 and Ichg2. Cap is the battery capacity, Res is the battery internal resistance, Qres is the thermal resistance of the battery to external heat dissipation, and Tbat delta is the change in battery temperature. Adding the ambient temperature to Tbat delta yields the battery temperature Tbat. Iterative calculations using the above parameters can create a parameter table of charging time and battery temperature variations.

In this embodiment, estimating the charging time Time_chg corresponding to when the battery temperature Tbat equals the charging temperature termination threshold Ttrg is equivalent to solving the function f(Time_chg)=Trg. As shown in FIG. 6A, the function has two solutions. Since the function is not a one-to-one monotonic function, scanning is required to solve it. In this embodiment, the maximum charging time Time_chg is set as the target for solving, aiming to find the latest charging time Time_chg that reaches the charging temperature termination threshold Ttrg.

In this embodiment, the control parameter is the charging time Time_chg, and the status parameter is the battery temperature Tbat. The estimated control parameter signal indicates the charging time Time_chg corresponding to when the battery temperature Tbat equals the charging temperature termination threshold Ttrg. The operation model corresponds to at least one battery characteristic, such as battery temperature Tbat, and at least one internal reference information, such as the parameter table of battery temperature versus charging time. The sequence direction indicates a decreasing charging time Time_chg direction, and the plural determination objects are plural status parameter values. The determination condition corresponds to a node determination condition for the determination objects.

According to the present invention, there are various practical applications that can be realized based on user needs. For example, in this embodiment, by calculating and creating a parameter table of charging time and battery temperature variations, a complete table of charging time and temperature changes throughout the charging process can be obtained. In one practical application for the user in this embodiment, the starting point for the first round of estimation is the longest charging time recorded in the table (i.e., until the battery is fully charged or even overcharged). The estimated result can be combined with the state of charge (SOC) and the corresponding open-circuit voltage (OCV) table to find the charged time corresponding to the current battery status (SOC). This charged time serves as the endpoint for the first round of estimation. After obtaining the estimated charging time that reaches the charging temperature termination threshold Ttrg, the result can be subtracted from the currently charged time to calculate the remaining time needed for proper charging. This practical application illustrates how to choose the first-round starting point and the first-round endpoint in this embodiment.

FIG. 6A shows the charging time Time_chg as the control parameter x and the battery temperature Tbat as the status parameter y. The sequence direction parameter indicates that the sequence direction is a decreasing control parameter, meaning that the control parameter x decreases until the first determination condition is met, yielding the solution. The first-round starting point is Str3, and the first-round endpoint is End3. The range between Str3 and End3 forms the limited range. This limited range is divided into plural sections, each with a fixed predetermined section interval Prd3. For example, but not limited to, as shown in FIG. 6A, the range between Str3 and End3 is divided into five sections, generating six control parameter values Xp1, Xp2, Xp3, Xp4, Xp5, and Xp6 marked sequentially according to the direction parameter. The estimation operation sequentially inputs control parameter values Xp1, Xp2, Xp3, Xp4, Xp5, and Xp6 into the operation model, i.e., function f(Time_chg), generating six corresponding status parameter values Yp1, Yp2, Yp3, Yp4, Yp5, and Yp6 as the determination objects. These status parameter values Yp1, Yp2, Yp3, Yp4, Yp5, and Yp6 are then compared with the target value, i.e., the charging temperature termination threshold Ttrg, generating plural comparison results, and the determination circuit checks whether these comparison results meet the node determination condition.

The node determination condition may include, but is not limited to, the difference between one of the status parameter values Yp1, Yp2, Yp3, Yp4, Yp5, and Yp6 and the charging temperature termination threshold Ttrg being smaller than the first predetermined difference. When the determination object satisfies the node determination condition, the corresponding control parameter value Xp1, Xp2, Xp3, Xp4, Xp5, or Xp6 is determined as the estimation result. In other words, as the control parameter values Xp1, Xp2, Xp3, Xp4, Xp5, and Xp6 are sequentially input into the function f(Time_chg), six corresponding status parameter values Yp1, Yp2, Yp3, Yp4, Yp5, and Yp6 are generated, and each is compared with the charging temperature termination threshold Ttrg. Once the difference is smaller than the first predetermined difference, the determination object satisfies the node determination condition, the estimation result is generated, and the estimation operation is completed, stopping further input of control parameter values into the operation model for calculating function f(Time_chg).

Another determination condition may include, but is not limited to, plural determination objects being plural sections, and the determination condition being a section determination condition. When one of the sections satisfies the section determination condition, such as the piecewise linear condition, the two control parameter values of the section, i.e., two consecutive control parameter values Xp1, Xp2, Xp3, Xp4, Xp5, or Xp6, and the two corresponding status parameter values Yp1, Yp2, Yp3, Yp4, Yp5, or Yp6, are used for linear interpolation, determining the interpolation point as the estimation result. That is, the estimation circuit 20 performs linear interpolation on the two control parameter values and the two status parameter values of the section, and the control parameter value obtained from the linear interpolation is determined as the estimation result, ending the estimation operation. The piecewise linear condition includes the difference between two consecutive control parameter values being smaller than the second predetermined difference, or the difference between two consecutive status parameter values corresponding to two control parameter values being smaller than the third predetermined difference. Once these differences are smaller than the second or third predetermined difference, the estimation result is determined, and further input of control parameter values into the operation model, including the function f(Time_chg), is stopped.

In this embodiment, as shown in FIG. 6A, when none of the status parameter values in the first round of estimation operation satisfies the determination condition, the estimation circuit defines the next limited range based on the two consecutive status parameter values Yp1 and Yp2 that first crossed the target value (i.e., the charging temperature termination threshold Ttrg) and their corresponding control parameter values Xp1 and Xp2. The same steps are repeated, including dividing the limited range into plural sections, inputting them into the function, and performing comparisons and determinations until the determination condition is satisfied and the estimation result is generated, as shown in FIG. 6B.

FIG. 6B shows that in the first round of estimation operation illustrated in FIG. 6A, none of the plural status parameter values Yp1, Yp2, Yp3, Yp4, Yp5, Yp6 satisfied the determination condition. Therefore, the two consecutive status parameter values Yp1 and Yp2, which first crossed the charging temperature termination threshold Ttrg, and their corresponding control parameter values Xp1 and Xp2, are defined as the limited range for the next round of estimation operation, i.e., the new limited range. The new starting point is Str4, and the new endpoint is End4. The range between Str4 and End4 forms the new limited range. This new limited range is divided into plural sections, each with a new fixed predetermined section interval Prd4. For example, but not limited to, as shown in FIG. 6B, the range between Str4 and End4 is divided into five sections, generating six control parameter values Xq1, Xq2, Xq3, Xq4, Xq5, and Xq6 marked sequentially according to the direction parameter. The estimation operation inputs control parameter values Xq1, Xq2, Xq3, Xq4, Xq5, and Xq6 into the operation model, i.e., function f(Time_chg), generating six corresponding status parameter values Yq1, Yq2, Yq3, Yq4, Yq5, and Yq6. These status parameter values Yq1, Yq2, Yq3, Yq4, Yq5, and Yq6 are then compared with the target value, i.e., the charging temperature termination threshold Ttrg, generating plural comparison results, and the estimation circuit checks whether these comparison results meet the determination condition.

The determination condition may include, but is not limited to, the difference between one of the status parameter values Yq1, Yq2, Yq3, Yq4, Yq5, and Yq6 and the charging temperature termination threshold Ttrg being smaller than the first predetermined difference. Once this difference is smaller than the first predetermined difference, the corresponding control parameter value Xq1, Xq2, Xq3, Xq4, Xq5, or Xq6 is determined as the estimation result. In other words, as the control parameter values Xq1, Xq2, Xq3, Xq4, Xq5, and Xq6 are sequentially input into the function f(Time_chg), six corresponding status parameter values Yq1, Yq2, Yq3, Yq4, Yq5, and Yq6 are generated. The status parameter values are then compared sequentially with the charging temperature termination threshold Ttrg, generating corresponding differences. Once a difference smaller than the first predetermined difference is found, the estimation result is generated, and further input of control parameter values Xq1, Xq2, Xq3, Xq4, Xq5, and Xq6 into the function f(Time_chg) is stopped.

For example, in this embodiment, when the difference between status parameter value Yq3 and the charging temperature termination threshold Ttrg is smaller than the first predetermined difference, the estimation result is generated, determining that the charging time corresponding to the battery temperature Tbat equal to the charging temperature termination threshold Ttrg is the control parameter value Xq3. Further input of control parameter values Xq4, Xq5, and Xq6 into the function f(Time_chg) is stopped, and status parameter values Yq4, Yq5, and Yq6 are not generated.

It should be noted that FIGS. 5A-5D and FIGS. 6A-6B illustrate two embodiments according to the present invention. However, the present invention is not limited to these embodiments. Other battery control parameter estimation methods can also be implemented according to the present invention.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “based on” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A battery control parameter estimation system, comprising:
a sensing circuit, configured to sense at least one battery property to generate at least one battery property signal;
a storage circuit, configured to store at least one internal reference information; and
an estimation circuit, configured to:
determine an operation model based on an estimated control parameter signal and the at least one battery property signal or the at least one internal reference information, wherein the operation model defines a control parameter and a status parameter, and defines the relationship between the control parameter and the status parameter; and
perform at least one round of estimation operation to generate an estimation result;
wherein the estimation operation comprises:
(a) dividing a limited range of the control parameter into a plurality of sections to generate corresponding a plurality of control parameter values;
(b) sequentially inputting the plural control parameter values into the operation model based on a sequential direction parameter to generate corresponding plural status parameter values;
(c) after generating each status parameter value, checking whether a corresponding determination object satisfies a determination condition;
(d) when the determination object satisfies the determination condition, determining the estimation result and ending the at least one round of estimation operation; and
(e) when all the determination objects corresponding to the plural status parameter values do not satisfy the determination condition, taking the two control parameter values corresponding to the two status parameter values that first cross a target value of the status parameter as the limited range for the next round of the estimation operation, and performing the next round of the estimation operation;
wherein the plural determination objects are the plural status parameter values or the plural sections;
wherein the determination condition is a node determination condition or a section determination condition corresponding to the determination object.

2. The battery control parameter estimation system of claim 1, wherein the at least one internal reference information includes a battery electrical characteristic table, an operation record, a calculation parameter, and/or a time counting value.

3. The battery control parameter estimation system of claim 1, wherein the at least one battery property includes a battery voltage, a battery current, and/or a battery temperature.

4. The battery control parameter estimation system of claim 1, wherein the control parameter is defined based on one of the at least one battery property signal or one of the at least one internal reference information.

5. The battery control parameter estimation system of claim 1, wherein the status parameter is defined based on one of the at least one battery property signal or one of the at least one internal reference information.

6. The battery control parameter estimation system of claim 1, wherein the estimated control parameter signal includes an operation model selection parameter, the sequential direction parameter, a first round starting point, and a first round endpoint;
wherein the operation model selection parameter is used to determine the corresponding operation model;
wherein the sequential direction parameter is used to indicate a sequential direction of the control parameter;
wherein the first round starting point and the first round endpoint define the limited range for the first round of estimation operation.

7. The battery control parameter estimation system of claim 1, wherein, during the same round of estimation operation, the interval length of each section in the plurality of sections is equal.

8. The battery control parameter estimation system of claim 1, wherein the step (d) of the estimation operation includes:
when a difference between one of the status parameter values of the plural status parameter values and the target value is smaller than a first predetermined difference, indicating that the node determination condition is satisfied, the estimation circuit determines the estimation result based on the corresponding control parameter value and ends the at least one round of estimation operation.

9. The battery control parameter estimation system of claim 1, wherein the step (d) of the estimation operation includes:
when one of the plural sections satisfies a piecewise linear condition, indicating that the section determination condition is satisfied, the estimation circuit performs linear interpolation based on the two control parameter values and the two status parameter values corresponding to the section, and determines the estimation result based on the control parameter value obtained from the linear interpolation, and ends the at least one round of estimation operation.

10. The battery control parameter estimation system of claim 9, wherein the piecewise linear condition includes:
a difference between the two status parameter values before and after the first crossing of the target value is smaller than a second predetermined difference, or a difference between the two control parameter values corresponding to the two status parameter values is smaller than a third predetermined difference.

11. The battery control parameter estimation system of claim 6, wherein the control parameter is a depth of discharge (DOD), and the status parameter is a battery voltage;
wherein the operation model selection parameter indicates an estimation of the depth of discharge corresponding to when the battery voltage is equal to a discharge voltage termination threshold;
wherein the sequential direction parameter indicates an increasing direction of the depth of discharge;
wherein the first round starting point is a present depth of discharge;
wherein the first round endpoint is an upper limit of the depth of discharge;
wherein the at least one battery property signal corresponding to the operation model includes the battery voltage, a battery temperature, and a battery current;
wherein the at least one internal reference information corresponding to the operation model includes the depth of discharge, an open circuit voltage (OCV) table corresponding to the depth of discharge, and a battery internal resistance table corresponding to the depth of discharge and the battery temperature.

12. The battery control parameter estimation system of claim 6, wherein the control parameter is a charging time, and the status parameter is a battery temperature;
wherein the operation model selection parameter indicates an estimation of the charging time corresponding to when the battery temperature is equal to a charging temperature termination threshold;
wherein the sequential direction parameter indicates a decreasing direction of the charging time;
wherein the first round starting point is an upper limit charging time point;
wherein the first round endpoint is a current charging time point;
wherein the at least one battery property signal corresponding to the operation model includes the battery temperature;
wherein the at least one internal reference information corresponding to the operation model includes a battery temperature table corresponding to the charging time and a time counting value.

13. A battery control parameter estimation method, comprising:
sensing at least one battery property with a sensing circuit to generate at least one battery property signal;
storing at least one internal reference information in a storage circuit;
determining an operation model with an estimation circuit based on an estimated control parameter signal and the at least one battery property signal or the at least one internal reference information, wherein the operation model defines a control parameter and a status parameter and defines the relationship between the control parameter and the status parameter; and
performing at least one round of estimation operation with the estimation circuit to generate an estimation result;
wherein the estimation operation comprises:
(a) dividing a limited range of the control parameter into a plurality of sections to generate a plurality of corresponding control parameter values;
(b) sequentially inputting the plural control parameter values into the operation model based on a sequential direction parameter to generate corresponding plural status parameter values;
(c) after generating each status parameter value, checking whether a corresponding determination object satisfies a determination condition;
(d) when the determination object satisfies the determination condition, determining the estimation result and ending the at least one round of estimation operation; and
(e) when all the determination objects corresponding to the plural status parameter values do not satisfy the determination condition, taking the two control parameter values corresponding to the two status parameter values that first cross a target value of the status parameter as the limited range for the next round of estimation operation, and performing the next round of estimation operation;
wherein the plural determination objects are the plural status parameter values or the plural sections;
wherein the determination condition is a node determination condition or a section determination condition corresponding to the determination object.

14. The battery control parameter estimation method of claim 13, wherein the at least one internal reference information includes a battery electrical characteristic table, an operation record, a calculation parameter, and/or a time counting value.

15. The battery control parameter estimation method of claim 13, wherein the at least one battery property includes a battery voltage, a battery current, and/or a battery temperature.

16. The battery control parameter estimation method of claim 13, wherein the control parameter is defined based on one of the at least one battery property signal or one of the at least one internal reference information.

17. The battery control parameter estimation method of claim 13, wherein the status parameter is defined based on one of the at least one battery property signal or one of the at least one internal reference information.

18. The battery control parameter estimation method of claim 13, wherein the estimated control parameter signal includes an operation model selection parameter, the sequential direction parameter, a first round starting point, and a first round endpoint;
wherein the operation model selection parameter is used to determine the corresponding operation model;
wherein the sequential direction parameter is used to indicate the sequential direction of one of the control parameters;
wherein the first round starting point and the first round endpoint define the limited range for the first round of estimation operation.

19. The battery control parameter estimation method of claim 13, wherein, during the same round of estimation operation, the interval length of each section in the plurality of sections is equal.

20. The battery control parameter estimation method of claim 13, wherein the step (d) of the estimation operation includes:
when a difference between one of the status parameter values of the plural status parameter values and the target value is smaller than a first predetermined difference, indicating that the node determination condition is satisfied, the estimation circuit determines the estimation result based on the corresponding control parameter value and ends the at least one round of estimation operation.

21. The battery control parameter estimation method of claim 13, wherein the step (d) of the estimation operation includes:
when one of the plural sections satisfies a piecewise linear condition, indicating that the section determination condition is satisfied, the estimation circuit performs linear interpolation based on the two control parameter values and the two status parameter values corresponding to the section, and determines the estimation result based on the control parameter value obtained from the linear interpolation, and ends the at least one round of estimation operation.

22. The battery control parameter estimation method of claim 21, wherein the piecewise linear condition includes:
a difference between the two status parameter values before and after the first crossing of the target value is smaller than a second predetermined difference, or a difference between the two control parameter values corresponding to the two status parameter values is smaller than a third predetermined difference.

23. The battery control parameter estimation method of claim 18, wherein the control parameter is a depth of discharge (DOD), and the status parameter is a battery voltage;
wherein the operation model selection parameter indicates an estimation of the depth of discharge corresponding to when the battery voltage is equal to a discharge voltage termination threshold;
wherein the sequential direction parameter indicates the increasing direction of the depth of discharge;
wherein the first round starting point is a current depth of discharge;
wherein the first round endpoint is related to an upper limit of the depth of discharge;
wherein the at least one battery property signal corresponding to the operation model includes the battery voltage, a battery temperature, and a battery current;
wherein the at least one internal reference information corresponding to the operation model includes the depth of discharge, an open circuit voltage (OCV) table corresponding to the depth of discharge, and a battery internal resistance table corresponding to the depth of discharge and the battery temperature.

24. The battery control parameter estimation method of claim 18, wherein the control parameter is a charging time, and the status parameter is a battery temperature;
wherein the operation model selection parameter indicates an estimation of the charging time corresponding to when the battery temperature is equal to a charging temperature termination threshold;
wherein the sequential direction parameter indicates a decreasing direction of the charging time;
wherein the first round starting point is an upper limit charging time point;
wherein the first round endpoint is a current charging time point;
wherein the at least one battery property signal corresponding to the operation model includes the battery temperature;
wherein the at least one internal reference information corresponding to the operation model includes a battery temperature table corresponding to the charging time and a time counting value.
